(19) United States
(12) Patent Application Publication
(10) Pub. No.: US 2022/0162742 A1
(43) Pub. Date: May 26, 2022

(54) SPUTTERING TARGET AND METHOD OF MANUFACTURING THE SAME, AND MEMORY DEVICE MANUFACTURING METHOD

(71) Applicant: SONY SEMICONDUCTOR SOLUTIONS CORPORATION, Kanagawa (JP)

(72) Inventors: Kazuhiro OHBA, Kanagawa (JP); Shuichiro YASUDA, Kanagawa (JP); Hiroaki SEI, Kanagawa (JP); Katsuhisa ARATANI, Kanagawa (JP)

(73) Assignee: SONY SEMICONDUCTOR SOLUTIONS CORPORATION, Kanagawa (JP)

(21) Appl. No.: 17/602,352

(22) PCT Filed: Mar. 13, 2020
(86) PCT No.: PCT/JP2020/011248

§ 371 Date: Oct. 8, 2021

(30) Foreign Application Priority Data
Apr. 17, 2019 (JP) 2019-078877

(51) Int. Cl. C23C 14/34

(52) U.S. Cl. CPC C23C 14/3414

(57) ABSTRACT

Provided are a sputtering target that makes it possible to form a chalcogenide material film with enhanced heat resistance, a method of manufacturing the sputtering target, and a memory device manufacturing method. The sputtering target includes an alloy containing a first component containing arsenic and selenium and a second component containing at least one of boron and carbon.

### TECHNICAL FIELD

The present disclosure relates to a sputtering target and a method of manufacturing the same, and a memory device manufacturing method.

### BACKGROUND ART

In recent years, as large-capacity nonvolatile memories, resistance change memories such as ReRAM (Resistance Random Access Memory) and PRAM (Phase-Change Random Access Memory) have been considered. Further, cross point memories having three-dimensional structures have been considered. A cross point memory can have a reduced cell area and a plurality of layers of cross point arrays stacked upward, and can therefore achieve a negative volatile memory having a larger capacity.

A cross point array has a structure having arranged therein memory cells each including a memory element and a switch element connected in series to a cross point between crossing wires. As the switch element, for example, a switch element using a chalcogenide material (ovonic threshold switch (OTS)) is given (for example, see PTL 1 and PTL 2).

### CITATION LIST

### Patent Literature

[PTL 1]

Japanese Patent Laid-open No. 2006-86526

[PTL 2]

Japanese Patent Laid-open No. 2010-157316

### SUMMARY

### Technical Problem

A chalcogenide material that is used for an OTS element is an amorphous material containing arsenic (As), selenium (Se), and the like, and tends to be low in heat resistance since the melting point of Se is particularly low. Thus, there is a possibility that the process temperature is limited to be low after the chalcogenide material film described above is formed.

The present disclosure has been made in view of such a circumstance and has an object to provide a sputtering target that makes it possible to form a chalcogenide material film with enhanced heat resistance, a method of manufacturing the sputtering target, and a memory device manufacturing method.

### Solution to Problem

According to an aspect of the present disclosure, there is provided a sputtering target including an alloy containing a first component containing arsenic and selenium and a second component containing at least one of boron and carbon. A chalcogenide material containing arsenic and selenium has enhanced heat resistance when containing at least one of boron and carbon. By sputtering using the sputtering target according to the aspect of the present disclosure, it is possible to form a chalcogenide material film with enhanced heat resistance.

### BRIEF DESCRIPTION OF DRAWINGS

FIG. 1 is a flowchart illustrating Example 1 of a method of manufacturing a sputtering target according to an embodiment of the present disclosure.

FIG. 2 is a flowchart illustrating Example 2 of the method of manufacturing the sputtering target according to the embodiment of the present disclosure.

FIG. 3 is a flowchart illustrating Example 3 of the method of manufacturing the sputtering target according to the embodiment of the present disclosure.

FIG. 4 is a flowchart illustrating Example 4 of the method of manufacturing the sputtering target according to the embodiment of the present disclosure.

FIG. 5 is a perspective view illustrating a configuration example of a memory cell array of an OTS element according to the embodiment of the present disclosure.

FIG. 6 is a sectional view illustrating a configuration example of a switch element according to the embodiment of the present disclosure.

FIG. 7 is a sectional view illustrating a configuration of a switch element according to a modified example of the embodiment of the present disclosure.

FIG. 8 is a graph illustrating the X-ray analysis pattern of a sputtering target according to Example 1 of the present disclosure.

FIG. 9 is a graph illustrating the measurement result of the X-ray analysis pattern of a sputtering target according to Example 2 of the present disclosure.

FIG. 10 is a photographic representation obtained by observing the surface of the sputtering target according to Example 2 of the present disclosure by a scanning electron microscope.

FIG. 11 is a schematic sectional view of the photographic representation of FIG. 10 taken along the line XI-XI′.

### DESCRIPTION OF EMBODIMENTS

### <Sputtering Target>

### Configuration Example

A sputtering target according to an embodiment of the present disclosure is, for example, a film-forming material that is used for forming a selective element of a cross point memory (for example, switch element 20 to be described later), and makes it possible to form a chalcogenide material film with enhanced heat resistance.

The sputtering target according to the embodiment of the present disclosure includes an alloy containing a first component containing arsenic (As) and selenium (Se) and a second component containing at least one of boron (B) and carbon (C). A chalcogenide material containing As and Se tends to be low in heat resistance since the melting point of Se is low, but has enhanced heat resistance when containing at least one of B and C. By sputtering using the sputtering target according to the embodiment of the present disclosure, a chalcogenide material film with enhanced heat resistance can be formed. Since the chalcogenide material film has the enhanced heat resistance, the upper limit temperature in the processes after the formation of the chalcogenide material film can be raised.

In the sputtering target according to the embodiment of the present disclosure, the second component is preferably dissolved in the phase of the first component to form a solid solution. The sputtering target according to the embodiment of the present disclosure preferably has, instead of a structure in which the second component that is sputtered at a different rate from the first component is dispersed in the phase of the first component, a monolayer structure in which the second component is dissolved and uniformly dispersed in the phase of the first component at the atomic level. That is, it is preferred that the particles or crystal grains of a compound containing the second component as its main component do not exist in the alloy of the sputtering target. With this, a uniform sputtering rate is achieved, so that a more homogeneous chalcogenide material film having a more uniform film thickness can be formed.

When the particles or crystal grains (hereinafter also simply referred to as “particle”) of a compound containing the second component as its main component exist in a sputtering target, there is a difference in sputtering rate between a portion in which the particles exist and a portion in which the particles do not exist. As a result, there is a possibility that a protrusion 40 (see FIG. 10 and FIG. 11 to be described later) that causes abnormal electrical discharge or arcing is formed in the sputtering target. However, when the second component is dissolved in the phase of the first component to form a solid solution, the sputtering rate is uniform over the entire sputtering target so that the formation of the protrusion 40 is prevented. With this, abnormal electrical discharge or arcing due to the protrusion 40 is prevented, so that the generation of particles can be prevented. A chalcogenide material film can be formed in a clean environment in which less particles are generated.

Note that, being dissolved to form a solid solution means that the second component is incorporated into the phase of the first component while the crystal structure of the first component is kept. For example, a case where the sputtering target according to the embodiment of the present disclosure contains B and C is assumed. Under this assumption, the surface of the sputtering target is observed using a scanning electron microscope (SEM) including an energy dispersive X-ray microanalyzer (EDX) to analyze a portion in which B and C or the particles of the compound thereof do not exist. When B and C are detected here, it can be said that B and C are dissolved in the phase containing As and Se to form a solid solution. For example, the fact that B and C are detected in EDX analysis on a homogeneous portion including no particle in an image observed by the SEM provides evidence that B and C are dissolved to form a solid solution.

The alloy of the sputtering target according to the embodiment of the present disclosure is preferably amorphous. With this, the sputtering target has no crystal grain boundary and does not have ununiformity due to crystal orientation or crystal grain boundaries. Thus, a uniform sputtering rate is achieved, so that a more homogeneous chalcogenide material film having a more uniform film thickness can be formed.

The content of the first component in the alloy described above is preferably 30 atomic percent (hereinafter referred to as “at %”) or more and 60 at % or less. When the content of the first component is less than 30 at % or more than 60 at %, an amorphous structure is difficult to obtain. Note that, at % is a value representing the percentage of the ratio of the number of atoms of a single element of any member (for example, sputtering target) to the number of atoms of all the elements.

The content of the second component in the alloy described above is preferably 5 at % or more and 35 at % or less. In a case where the content of the second component is less than 5 at %, there is a possibility that a chalcogenide material film formed using the sputtering target does not have sufficient heat resistance. Further, when the content of the second component is more than 35 at %, the thickness of the chalcogenide material film is easy to vary. For example, in a selective element using a chalcogenide material film as a variable resistive film, there is a possibility that the thickness of the chalcogenide material film varies to fluctuate the threshold, and the switching characteristics may deteriorate.

The first component may further contain one or more elements selected from germanium (Ge), gallium (Ga), and silicon (Si). Germanium and silicon are effective for enhancing the thermal stability of the amorphous structure of a chalcogenide material film formed using the sputtering target. Being thermally stable means that a chalcogenide material film stably maintains its amorphous structure when being heated. Gallium is effective for reducing a variation in thickness of a chalcogenide material film. When the thermal stability of a chalcogenide material film is increased or a variation in film thickness is reduced, the heat resistance of a selective element using the chalcogenide material film as a variable resistive film can be increased, or the switching characteristics can be enhanced since a variation in threshold is reduced.

The content of germanium in the alloy described above may be 0 at % or more and 20 at % or less. When the content of germanium is more than 20 at %, there is a possibility that the composition of the chalcogenide material film exceeds the optimal range, and the electrical characteristics of the switch element may thus deteriorate.

The content of gallium in the alloy described above may be 0 at % or more and 20 at % or less. When the content of germanium is more than 20 at %, there is a possibility that the composition of the chalcogenide material film exceeds the optimal range, and the electrical characteristics of the switch element may thus deteriorate.

The content of silicon in the alloy described above may be 0 at % or more and 20 at % or less. When the content of silicon is more than 20 at %, there is a possibility that the composition of the chalcogenide material film exceeds the optimal range, and the electrical characteristics of the switch element may thus deteriorate.

Now, with reference to the drawings, four examples are described as a method of manufacturing the sputtering target according to the embodiment of the present disclosure. Note that, in the illustration of the drawings that are referred to in the following description, the same or similar portions are denoted by the same or similar reference symbols. Further, it should be noted that the drawings are schematic and hence the relationship between the thickness and the planar size, the ratio of the layer thicknesses, and the like are different from the reality. The dimensional relationship or proportion is sometimes different between the drawings, as a matter of course.

### Example 1 of Manufacturing Method

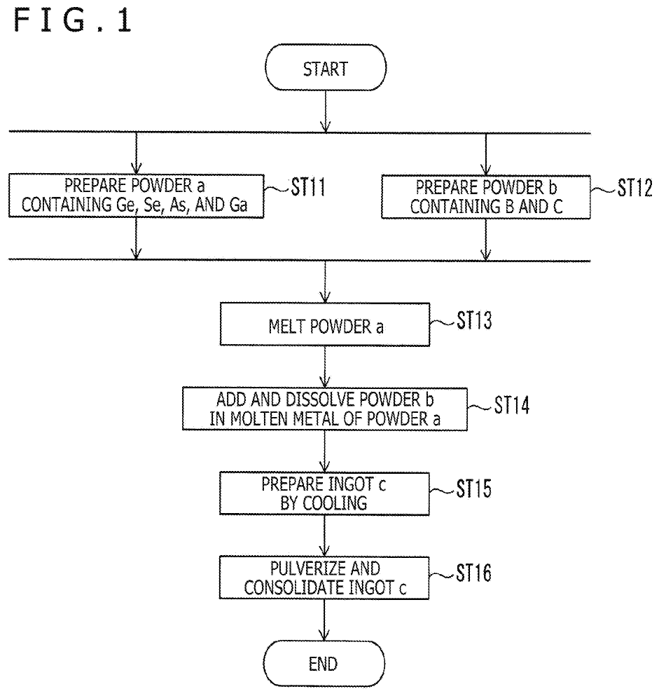

FIG. 1 is a flowchart illustrating Example 1 of a method of manufacturing the sputtering target according to the embodiment of the present disclosure. Manufacturing the sputtering target uses various devices such as a compounding device configured to compound components serving as raw materials of the sputtering target, an introduction device configured to introduce the compound component into a quartz tube, a pump device configured to evacuate the quartz tube, an electric furnace configured to melt the components, a pulverization device configured to pulverize an ingot obtained by cooling the melted components, such as a ball mill, and a hot press configured to sinter the powder to consolidate the powder. In the embodiment of the present disclosure, these devices are collectively referred to as “manufacturing device.” Note that, a worker may perform at least some processing that is performed by the manufacturing device.

As illustrated in FIG. 1, the manufacturing device prepares, as the first component, powder a containing germanium (Ge), selenium (Se), arsenic (As), and gallium (Ga) (Step ST11). The purity of Ge, Se, As, and Ga is preferably increased in advance. Further, around or in parallel to Step ST11, the manufacturing device prepares, as the second component, powder b containing boron (B) and carbon (C) (Step ST12). For example, the manufacturing device pulverizes high-purity B₄C that is the compound of B and C to prepare the powder b (an example of “solute” of the present disclosure).

Next, the manufacturing device melts the prepared powder a to prepare the molten metal of an alloy containing Ge, Se, As, and Ga (an example of “first alloy” of the present disclosure; hereinafter also referred to as “GeSeAsGa alloy”) (Step ST13). Next, the manufacturing device adds and dissolves the powder b in the molten metal of the powder a (molten metal of GeSeAsGa alloy) (Step ST14). With this, the liquid phase of an alloy containing Ge, Se, As, Ga, B, and C in which B and C are dissolved in the phase of the GeSeAsGa alloy (an example of “alloy” of the present disclosure; hereinafter also referred to as “GeSeAsGaBC alloy”) is prepared.

In the GeSeAsGa alloy, particles or crystal grains containing B and C as their main components tend to remain. This is because the melting points of B and C contained in the powder b are at least 1,000° C. higher than the melting point of the GeSeAsGa alloy. However, in Example 1 of the manufacturing method, B and C are dissolved in the molten metal of the GeSeAsGa alloy, so that B and C can be uniformly dispersed in the phase of the GeSeAsGa alloy at the atomic level. With this, the liquid phase of the GeSeAsGaBC alloy in which particles or crystal grains containing B and C as their main components do not exist (or few particles or crystal grains exist) can be prepared.

Next, the manufacturing device cools the liquid phase of the GeSeAsGaBC alloy to prepare an ingot c of the GeSeAsGaBC alloy (Step ST15). As described above, in the liquid phase of the GeSeAsGaBC alloy, B and C are uniformly dispersed at the atomic level. Thus, also in the ingot c, which is formed by cooling the liquid phase of the GeSeAsGaBC alloy, B and C are uniformly dispersed at the atomic level. In the ingot c, particles or crystal grains containing B and C as their main components do not exist. In the ingot c, B and C are dissolved in the phase of the GeSeAsGa alloy to form a solid solution.

Next, the manufacturing device pulverizes the ingot c in an argon (Ar) atmosphere to prepare raw material powder from the GeSeAsGaBC alloy. The ingot c is pulverized to obtain the raw material powder using the ball mill, for example. Next, the manufacturing device consolidates the raw material powder and forms it into a desired shape (Step ST16). For example, the raw material powder is consolidated using the hot press. By the hot press, the raw material powder can be pressure molded at high temperature under vacuum. Through the steps described above, the sputtering target according to the embodiment is complete.

### Example 2 of Manufacturing Method

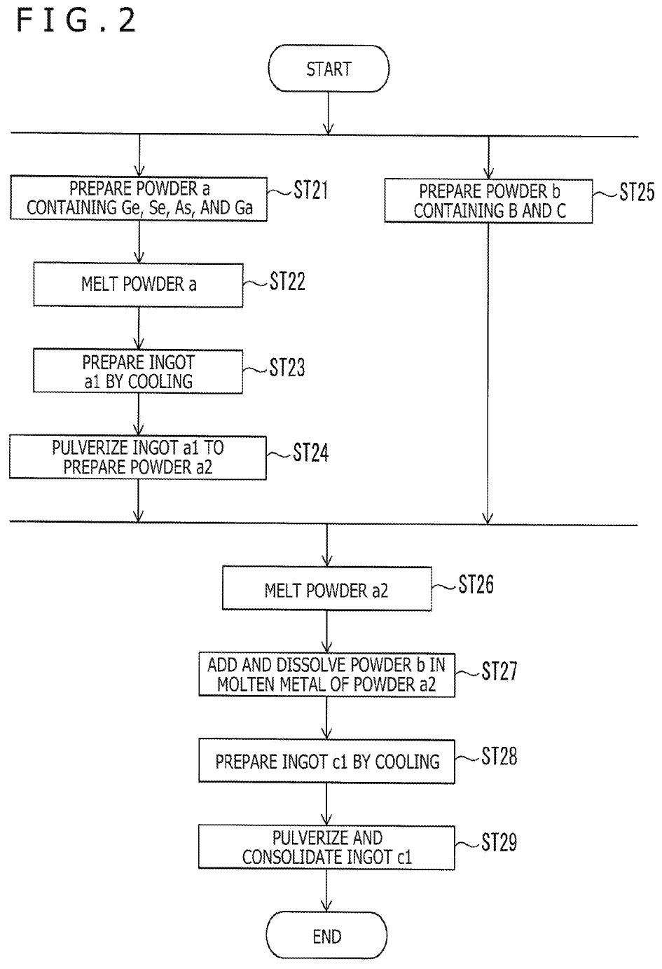

FIG. 2 is a flowchart illustrating Example 2 of the method of manufacturing the sputtering target according to the embodiment of the present disclosure. As illustrated in FIG. 2, the manufacturing device prepares, as the first component, the powder a containing Ge, Se, As, and Ga (Step ST21). Next, the manufacturing device melts the prepared powder a (Step ST22). With this, the liquid phase of a GeSeAsGa alloy is prepared. Next, the manufacturing device cools the liquid phase of the GeSeAsGa alloy to prepare an ingot a1 of the GeSeAsGa alloy (Step ST23). Next, the manufacturing device pulverizes the ingot a1 in an Ar atmosphere to prepare powder a2 of the GeSeAsGa alloy (Step ST24). The ingot a1 is pulverized using the ball mill, for example.

Around or in parallel to Steps ST21 to ST24, the manufacturing device prepares, as the second component, the powder b containing B and C (Step ST25). Next, the manufacturing device melts the powder a2 to prepare the molten metal of the powder a2 (molten metal of GeSeAsGa alloy) (Step ST26). Then, the manufacturing device adds and dissolves the powder b in the molten metal of the GeSeAsGa alloy (Step ST27). With this, the liquid phase of a GeSeAsGaBC alloy is prepared. In the liquid phase of the GeSeAsGaBC alloy, B and C are dissolved in the phase of the GeSeAsGa alloy.

Next, the manufacturing device cools the liquid phase of the GeSeAsGaBC alloy to prepare an ingot c1 of the GeSeAsGaBC alloy (Step ST28). The ingot c1 is a solid solution in which the second component is dissolved in the solid phase of the first component to form a solid solution. Next, the manufacturing device pulverizes the ingot c1 in the Ar atmosphere to prepare raw material powder. Next, the manufacturing device consolidates the raw material powder and forms it into a desired shape (Step ST29). The raw material powder is consolidated using the hot press, for example. Through the steps described above, the sputtering target according to the embodiment is complete.

With Example 2 of the manufacturing method, which includes more steps than Example 1 of the manufacturing method, the purity of the GeSeAsGa alloy is increased in Steps ST23 and ST24, so that a higher quality sputtering target can be manufactured.

### Example 3 of Manufacturing Method

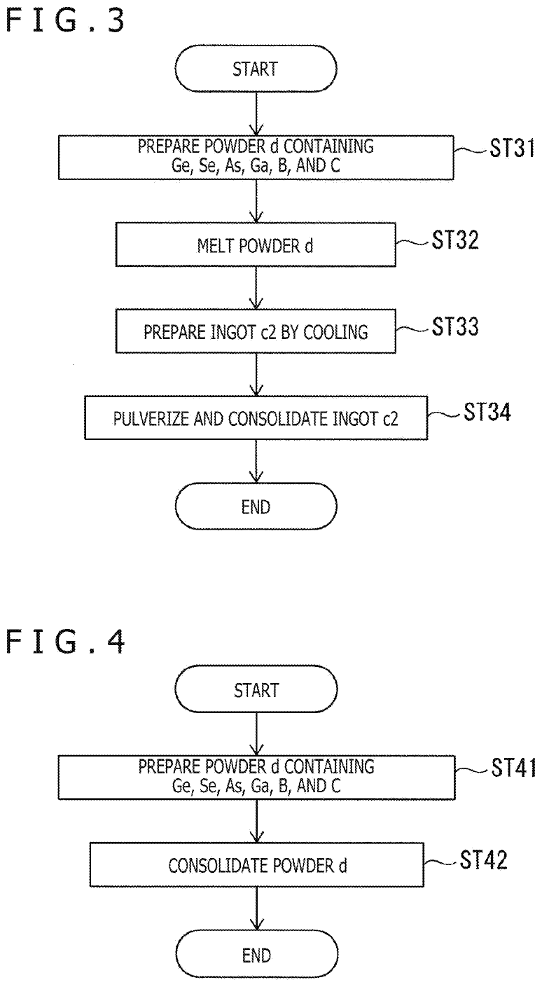

FIG. 3 is a flowchart illustrating Example 3 of the method of manufacturing the sputtering target according to the embodiment of the present disclosure. As illustrated in FIG. 3, the manufacturing device prepares powder d containing Ge, Se, As, Ga, B, and C (Step ST31). In Step ST31, the two types of powder a and b described in Examples 1 and 2 of the manufacturing method may be prepared in advance and the two types of powder a and b may be mixed to prepare the powder d.

Next, the manufacturing device melts the prepared powder d (Step ST32). With this, the liquid phase of a GeSeAsGaBC alloy is prepared. In the liquid phase of the GeSeAsGaBC alloy, B and C are dissolved in the phase of the GeSeAsGa alloy. Next, the manufacturing device cools the liquid phase of the GeSeAsGaBC alloy to prepare an ingot c2 of the GeSeAsGaBC alloy (Step ST33). The ingot c2 is a solid solution in which the second component is dissolved in the solid phase of the first component to form a solid solution. Next, the manufacturing device pulverizes the ingot c2 in an Ar atmosphere to obtain raw material powder. Next, the manufacturing device consolidates the raw material powder and forms it into a desired shape (Step ST34). The powder d is consolidated using the hot press, for example. Through the steps described above, the sputtering target according to the embodiment is complete.

### Example 4 of Manufacturing Method

FIG. 4 is a flowchart illustrating Example 4 of the method of manufacturing the sputtering target according to the embodiment of the present disclosure. As illustrated in FIG. 4, the manufacturing device prepares the powder d containing Ge, Se, As, Ga, B, and C (Step ST41). Next, the manufacturing device consolidates the powder d and forms it into a desired shape (Step ST42). The raw material powder is consolidated using the hot press, for example. Through the steps described above, the sputtering target according to the embodiment is complete.

### Modified Example

In the embodiment described above, the first component contains Ge, Se, As, and Ga, but the embodiment is merely an example. The first component may only contain As and Se, or may contain, in addition to As and Se, Ge and Si, Ga and Si, or Si. Further, in the embodiment described above, the second component contains B and C, but the embodiment is merely an example. The second component may only contain one of B and C.

### <Memory Device>

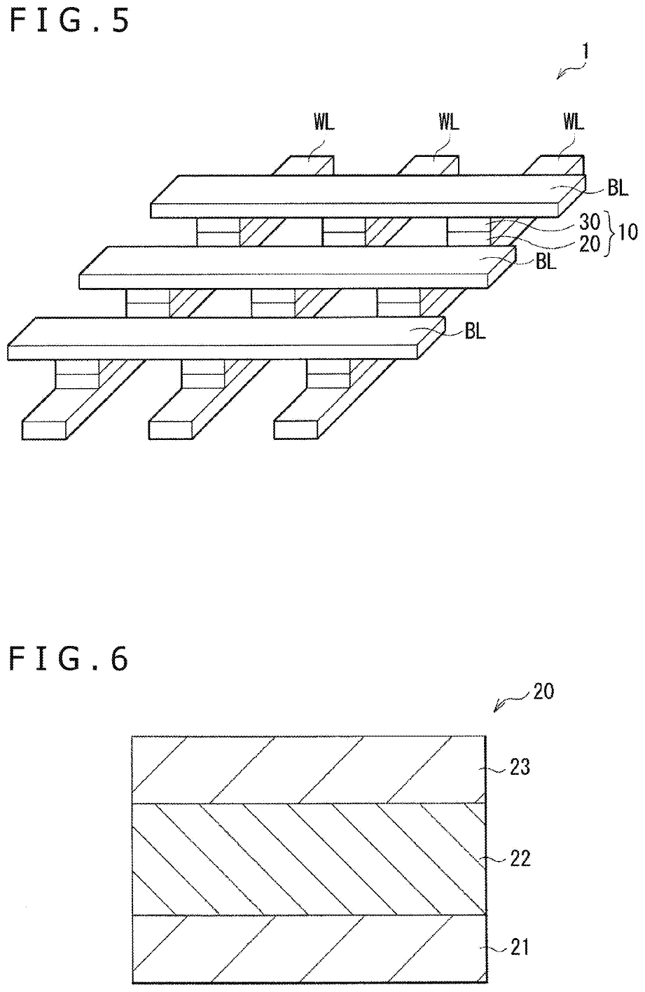

Next, a configuration example of an OTS element manufactured using the sputtering target according to the embodiment of the present disclosure (an example of “memory device” of the present disclosure) is described. FIG. 5 is a perspective view illustrating a configuration example of a memory cell array 1 of an OTS element according to the embodiment of the present disclosure. FIG. 6 is a sectional view illustrating a configuration example of the switch element 20 according to the embodiment of the present disclosure.

As illustrated in FIG. 5, the memory cell array 1 has what is called a cross point array structure and includes, for example, a memory cell 10 at a position at which a word line WL and a bit line BL cross each other (cross point). The word lines WL extend in a common direction. The bit lines BL extend in a common direction different from the extending direction of the word line WL (for example, a direction orthogonal to the extending direction of the word line WL).

The memory cell 10 includes a memory element 30 and the switch element 20 connected to the memory element 30 in series. For example, the memory element 30 is disposed on the bit line BL side, and the switch element 20 is disposed on the word line WL side. Alternatively, the memory element 30 may be disposed on the word line WL side, and the switch element 20 may be disposed on the bit line BL side.

The switch element 20 illustrated in FIG. 6 is the selective element of the cross point memory and is an element for selectively operating any memory element 30 illustrated in FIG. 5. The switch element 20 is connected to the memory element 30 in series and includes a lower electrode 21, a switch layer 22 (an example of “resistance change layer” of the present disclosure), and an upper electrode 23 in this order. The lower electrode 21 and the upper electrode 23 include wire materials that are used for the semiconductor process, for example, tungsten (W), tungsten nitride (WN), titanium nitride (TiN), copper (Cu), aluminum (Al), molybdenum (Mo), tantalum (Ta), tantalum nitride (TaN), and silicide.

The switch layer 22 is formed using the sputtering target according to the embodiment of the present disclosure. With this, the switch layer 22 has the same composition as the sputtering target according to the embodiment of the present disclosure. Specifically, the switch layer 22 contains the first component containing As and Se and the second component containing at least any one of B and C.

The switch layer 22 has low resistance when being applied with a voltage equal to or larger than a predetermined threshold voltage (switching threshold voltage), and has high resistance when being applied with a voltage smaller than the above-mentioned threshold voltage (switching threshold voltage). The amorphous structure of the switch layer 22 is stably maintained irrespective of the application of a voltage pulse or current pulse from a power supply circuit (pulse application means), which is not illustrated, through the lower electrode 21 and the upper electrode 23.

### Modified Example

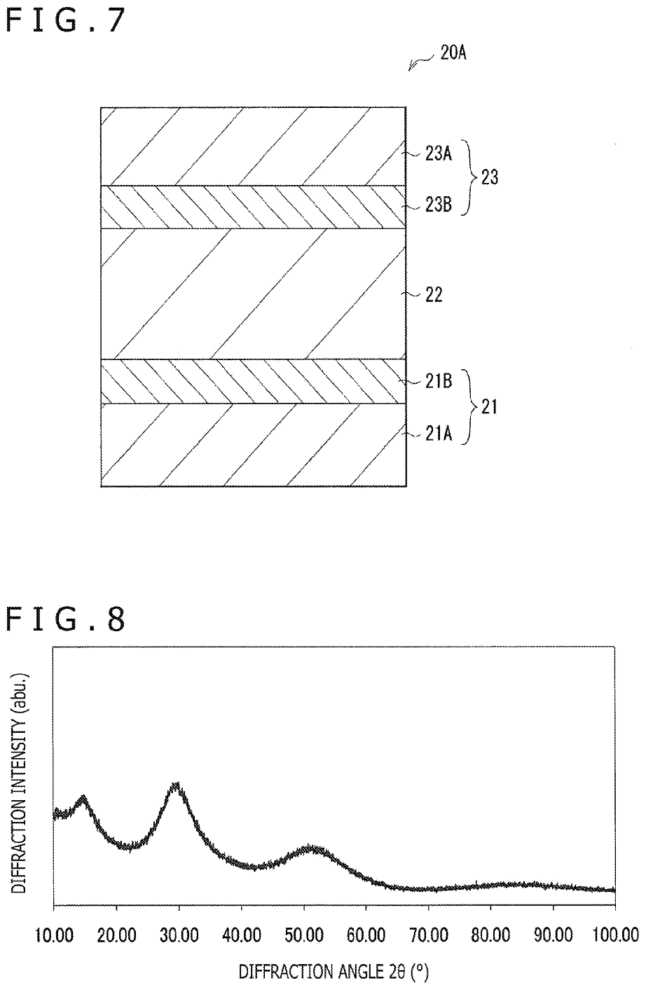

The configuration of the switch element 20 manufactured using the sputtering target according to the embodiment of the present disclosure is not limited to the aspect illustrated in FIG. 6. FIG. 7 is a sectional view illustrating the configuration of a switch element 20A according to a modified example of the embodiment of the present disclosure. As illustrated in FIG. 7, in the switch element 20A, the lower electrode 21 is formed as the stack of a metal layer 21A and a carbon-containing layer 21B, and the upper electrode 23 is formed as the stack of a metal layer 23A and a carbon-containing layer 23B.

The lower electrode 21 has the configuration in which the metal layer 21A and the carbon-containing layer 21B are stacked in this order. The upper electrode 23 has the configuration in which the carbon-containing layer 23B and the metal layer 23A are stacked in this order. The metal layers 21A and 23A include wire materials that are used for the semiconductor process, for example, W, WN, TiN, Cu, Al, Mo, Ta, TaN, and silicide.

The carbon-containing layers 21B and 23B are held in contact with the switch layer 22. The carbon-containing layers 21B and 23B are formed using carbon (C) and contain at least one of germanium (Ge), phosphorus (P), and arsenic (As) as additive elements. The additive elements added to the carbon-containing layers 21B and 23B are diffused near the interfaces with the switch layer 22 by thermal diffusion or the like in the process. With this, favorable interfaces are formed between the carbon-containing layer 21B and the switch layer 22 and between the carbon-containing layer 23B and the switch layer 22, with the result that the occurrence of leakage current and a variation in switching threshold voltage can be reduced. Further, with the additive elements diffused near the interface between the carbon-containing layer 21B and the switch layer 22 and near the interface between the carbon-containing layer 23B and the switch layer 22, the adhesion between the lower electrode 21 and the switch layer 22 and the adhesion between the upper electrode 23 and the switch layer 22 are each enhanced.

### EXAMPLES

Next, examples of the present disclosure are described.

### Example 1

High-purity germanium (Ge), selenium (Se), arsenic (As), and liquid gallium (Ga) raw material were compounded at a ratio of 11.8 at % of Ge, 49.4 at % of Se, 32.9 at % of As, and 5.9 at % of Ga. The compound powder was put into a quartz tube, and the quartz tube was evacuated and sealed. Next, the quartz tube was disposed in the electric furnace, and the powder in the quartz tube was melted by heat and then cooled to prepare the ingot of a GeSeAsGa alloy. Next, the quartz tube was partly cut and filled with a predetermined amount of B₄C that was a high-purity compound to achieve a total composition ratio of 10 at % of Ge, 42 at % of Se, 28 at % of As, 5 at % of Ga, 12 at % of B, and 3 at % of C.

Next, the quartz tube was evacuated and sealed again. After that, the quartz tube was disposed in the electric furnace, and the ingot of the GeSeAsGa alloy and the B₄C compound in the quartz tube were melt. Here, the ingot of the GeSeAsGa alloy having a low melting point was melted first, and when the alloy having the low melting point was completely melted, the quartz tube was swung to dissolve B₄C. The resultant was then cooled to obtain the ingot of a GeSeAsGaBC alloy having a uniform fine structure and composition.

Next, the ingot of the GeSeAsGaBC alloy was pulverized by the ball mill in an Ar atmosphere to obtain raw material powder. Then, the raw material powder was consolidated by the hot press and formed into a desired shape to obtain a sputtering target. The X-ray diffraction pattern of the obtained sputtering target is illustrated in FIG. 8.

FIG. 8 is a graph illustrating the X-ray analysis pattern of the sputtering target according to Example 1 of the present disclosure. In FIG. 8, the horizontal axis indicates the X-ray diffraction angle 2θ (°), and the vertical axis indicates the X-ray diffraction intensity in an arbitrary unit (abu.). As illustrated in FIG. 8, in the sputtering target according to Example 1, a clear analysis peak due to the crystal phase is not observed. From this result, it can be confirmed that the sputtering target according to Example 1 has an amorphous single phase structure.

A chalcogenide material was sputtered on a 12-inch Si wafer using this sputtering target to form a film of 20 nm thick. The particles in this case were measured by a known particle scanning measurement device, and it was confirmed that an increase in number of particles having 100 nm or larger before and after the film was formed was 50, and the generation of particles due to sputtering was prevented.

For this, it is conceivable that the GeSeAsGaBC alloy prepared by dissolving B and C has the single phase structure and there is thus no difference in sputter rate due to phase difference. It is conceivable that, since the protrusion 40 (see FIG. 10 and FIG. 11 to be described later) is hardly formed on the surface of the sputtering target when the surface is sputtered, abnormal electrical discharge due to the protrusion 40 is difficult to occur and less particles are thus generated.

As in Example 1, when the composition ratio of the elements of a sputtering target is set to an appropriate value, the entire sputtering target can be formed as an amorphous structure. That is, in the entire sputtering target, the existence of the particles or crystal grains of a compound containing B and C as its main component can be prevented. With this, the ununiformity of fine structure or composition that is unavoidable in normal polycrystalline materials, such as crystal grain boundaries, can be avoided, so that the generation of particles in sputtering can be prevented more preferably.

### Example 2

High-purity germanium (Ge), selenium (Se), arsenic (As), and liquid gallium (Ga) raw material were compounded at a ratio of 11.8 at % of Ge, 49.4 at % of Se, 32.9 at % of As, and 5.9 at % of Ga. The compound powder was put into a quartz tube, and the quartz tube was evacuated and sealed. Next, the quartz tube was disposed in the electric furnace, and the powder in the quartz tube was melted by heat and then cooled to prepare the ingot of a GeSeAsGa alloy. After that, the ingot was pulverized by the ball mill in an Ar atmosphere to obtain raw material powder.

Next, B₄C powder that was a high-purity compound was added to and mixed with the GeSeAsGa alloy that was the raw material powder to achieve the composition ratio of the mix powder of 10 at % of Ge, 42 at % of Se, 28 at % of As, 5 at % of Ga, 12 at % of B, and 3 at % of C.

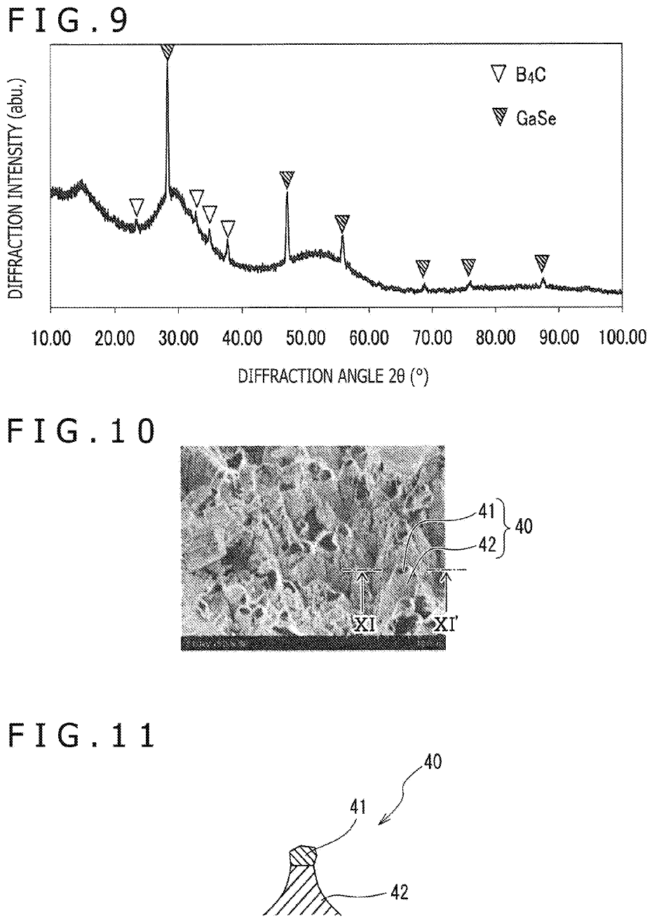

Next, the mix powder was consolidated by the hot press and formed into a desired shape to obtain a sputtering target. The X-ray diffraction pattern of the obtained sputtering target is illustrated in FIG. 9.

FIG. 9 is a graph illustrating the measurement result of the X-ray analysis pattern of the sputtering target according to Example 2 of the present disclosure. In FIG. 9, the horizontal axis indicates the X-ray diffraction angle 2θ (°), and the vertical axis indicates the X-ray diffraction intensity (abu.). As illustrated in FIG. 9, in the sputtering target according to Example 2, broad peaks due to the amorphous phase and diffraction peaks due to the B₄C phase are observed. From this result, it can be confirmed that the sputtering target according to Example 2 has a structure in which the particles of B₄C are dispersed in the amorphous phase.

A chalcogenide material was sputtered on a 12-inch Si wafer using this sputtering target to form a film of 20 nm thick. The particles in this case were measured by a known particle scanning measurement device, and it was confirmed that an increase in number of particles was larger than that in Example 1. The inventors of the present invention have investigated the cause of the increase in number of particles.

FIG. 10 is a photographic representation obtained by observing the surface of the sputtering target according to Example 2 of the present disclosure by the scanning electron microscope (SEM). FIG. 11 is a schematic sectional view of the photographic representation of FIG. 10 taken along the line XI-XI′. A portion subjected to more sputtering, namely, what is called an erosion portion of the sputtering target according to Example 2 was observed by the SEM, and the protrusion 40 as illustrated in FIG. 10 and FIG. 11 was found. B and C were detected from a top portion 41 of the protrusion 40, and As, Se, and other constituent elements were detected in a skirt portion 42 of the protrusion 40. It is conceivable that the protrusion 40 described above is formed when the B₄C particles are shaved off slightly by low speed sputtering and remain, while the AsSe alloy portion is shaved off largely by high speed sputtering. It is conceivable that abnormal electrical discharge such as micro-arcing occurred due to such ununiformity or shape with the result that the number of particles was increased.

### Other Embodiments

As described above, the present disclosure is described by means of the embodiment, modified examples, and examples, but it is not to be understood that the description and drawings that constitute parts of the disclosure limit the present disclosure. Various alternative embodiments, examples, and operating techniques will become apparent to those skilled in the art from the disclosure. For example, in the description of the embodiment of the present disclosure, the ingot of the GeSeAsGaBC alloy is pulverized and consolidated to form the sputtering target into the desired shape, but other methods may be used. For example, the GeSeAsGaBC alloy may be poured into a mold to form the sputtering target into the desired shape.

In such a way, it goes without saying that the present technology includes various embodiments and the like not described herein. At least one of various types of omission, replacement, and modification of the components can be made without departing from the gist of the embodiment, modified examples, and examples described above. Further, the effects described herein are merely exemplary and not limitative, and other effects may be provided.

Note that, the present disclosure can also take the following configurations.

(1)

A sputtering target including:

an alloy containing a first component containing arsenic and selenium and a second component containing at least one of boron and carbon.

(2)

The sputtering target according to Item (1), in which the second component is dissolved in a phase of the first component to form a solid solution.

(3)

The sputtering target according to Item (1) or (2), in which the alloy does not contain a particle or a crystal grain of a compound containing the second component as a main component.

(4)

The sputtering target according to any one of Items (1) to (3), in which the alloy is amorphous.

(5)

The sputtering target according to any one of Items (1) to (4), in which content of the first component in the alloy is 30 atomic percent or more and 60 atomic percent or less.

(6)

The sputtering target according to any one of Items (1) to (5), in which content of the second component in the alloy is 5 atomic percent or more and 35 atomic percent or less.

(7)

The sputtering target according to any one of Items (1) to (6), in which the first component further contains one or more elements selected from germanium, gallium, and silicon.

(8)

The sputtering target according to Item (7), in which content of the germanium in the alloy is 0 atomic percent or more and 20 atomic percent or less.

(9)

The sputtering target according to Item (7) or (8), in which content of the gallium in the alloy is 0 atomic percent or more and 20 atomic percent or less.

(10)

The sputtering target according to any one of Items (7) to (9), in which content of the silicon in the alloy is 0 atomic percent or more and 20 atomic percent or less.

A method of manufacturing a sputtering target, the method including the steps of:

preparing a liquid phase in which a second component containing at least one of boron and carbon is dissolved in a phase of a first component containing arsenic and selenium; and

cooling the liquid phase to form an ingot.

(12)

The method of manufacturing a sputtering target according to Item (11), in which the step of preparing the liquid phase includes
a step of preparing a molten metal of a first alloy containing the first component, and
a step of dissolving the second component in the molten metal.
   (13)

The method of manufacturing a sputtering target according to Item (12), in which, in the step of dissolving the second component, a solute containing the second component and having a melting point at least 1,000° C. higher than a melting point of the first alloy is dissolved in the molten metal.

(14)

A memory device manufacturing method including:

forming a resistance change layer with use of a sputtering target including an alloy containing a first component containing arsenic and selenium and a second component containing at least one of boron and carbon.

### Reference Signs List

1: Memory cell array
10: Memory cell
20, 20A: Switch element
21: Lower electrode
21A, 23A: Metal layer
21B, 23B: Carbon-containing layer
22: Switch layer
23: Upper electrode
30: Memory element
40: Protrusion
41: Top portion
42: Skirt portion
a, a2, b: Powder
a1, c, c1, c2: Ingot
BL: Bit line
WL: Word line

What is claimed is:

1. A sputtering target comprising:
an alloy containing a first component containing arsenic and selenium and a second component containing at least one of boron and carbon.

2. The sputtering target according to claim 1, wherein the second component is dissolved in a phase of the first component to form a solid solution.

3. The sputtering target according to claim 1, wherein the alloy does not contain a particle or a crystal grain of a compound containing the second component as a main component.

4. The sputtering target according to claim 1, wherein the alloy is amorphous.

5. The sputtering target according to claim 1, wherein content of the first component in the alloy is 30 atomic percent or more and 60 atomic percent or less.

6. The sputtering target according to claim 1, wherein content of the second component in the alloy is 5 atomic percent or more and 35 atomic percent or less.

7. The sputtering target according to claim 1, wherein the first component further contains one or more elements selected from germanium, gallium, and silicon.

8. The sputtering target according to claim 7, wherein content of the germanium in the alloy is 0 atomic percent or more and 20 atomic percent or less.

9. The sputtering target according to claim 7, wherein content of the gallium in the alloy is 0 atomic percent or more and 20 atomic percent or less.

10. The sputtering target according to claim 7, wherein content of the silicon in the alloy is 0 atomic percent or more and 20 atomic percent or less.

11. A method of manufacturing a sputtering target, the method comprising the steps of:
preparing a liquid phase in which a second component containing at least one of boron and carbon is dissolved in a phase of a first component containing arsenic and selenium; and
cooling the liquid phase to form an ingot.

12. The method of manufacturing a sputtering target according to claim 11, wherein the step of preparing the liquid phase includes
a step of preparing a molten metal of a first alloy containing the first component, and
a step of dissolving the second component in the molten metal.

13. The method of manufacturing a sputtering target according to claim 12, wherein, in the step of dissolving the second component, a solute containing the second component and having a melting point at least 1,000° C. higher than a melting point of the first alloy is dissolved in the molten metal.

14. A memory device manufacturing method comprising:
forming a resistance change layer with use of a sputtering target including an alloy containing a first component containing arsenic and selenium and a second component containing at least one of boron and carbon.
